(19) United States
(12) Patent Application Publication
(10) Pub. No.: US 2006/0132872 A1
(43) Pub. Date: Jun. 22, 2006

(54) System and method for proofing a page for color discriminability problems

(76) Inventor: Giordano B. Beretta, Palo Alto, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/017,405

(22) Filed: Dec. 20, 2004

(51) Int. Cl. G03F 3/08

(52) U.S. Cl. 358/518

(57) ABSTRACT

An automated method for proofing a page for color discriminability problems includes converting a first color of a first object appearing on the page and a second color of a second object appearing on the page to a perceptually uniform color space. The method includes identifying a difference between the first color and the second color in the perceptually uniform color space. The method includes comparing the difference to a threshold to determine if the first color and the second color are discriminable.

### CROSS-REFERENCE TO RELATED APPLICATION

This application is related to U.S. patent application Ser. No. ______, attorney docket No. 200404710-1, filed on the same date as the present application, and entitled SYSTEM AND METHOD FOR DETERMIN I NG AN IMAGE FRAME COLOR FOR AN IMAGE FRAME.

### BACKGROUND

The Internet has enabled new digital printing workflows that are distributed, media-less, and share knowledge resources. One new application in the commercial printing field is referred to as “variable data printing” (VDP), where a rich template is populated with different data for each copy, typically merged from a database or determined algorithmically. In variable data printing, pages may be created with an automated page layout system, which places objects within a page and automatically generates a page layout that is pleasing to a user.

Variable data printing examples include permission-based marketing, where each copy is personalized with a recipient name, and the contents are chosen based on parameters like sex, age, income, or ZIP code; do-it-yourself catalogs, where customers describe to an e-commerce vendor their purchase desires, and vendors create customer catalogs with their offerings for that desire; customized offers in response to a tender for bids, with specification sheets, white papers, and prices customized for the specific bid; insurance and benefit plans, where customers or employees receive a contract with their specific information instead of a set of tables from which they can compute their benefits; executive briefing materials; and comic magazines, where the characters can be adapted to various cultural or religious sensitivities, and the text in the bubbles can be printed in the language of the recipient.

In traditional printing, the final proof is inspected visually by the customer and approved. In variable data printing, each printed copy is different, and it is not practical to proof each copy. When there are small problems, like a little underflow or overflow, the elements or objects on a page can be slightly nudged, scaled, or cropped (in the case of images). When the overflow is larger, the failure can be fatal, because objects will overlap and may no longer be readable or discriminable because the contrast is too low. When pages are generated automatically and not proofed, gross visual discriminability errors can occur.

Similarly, when background and foreground colors are automatically selected from limited color palettes, color combinations can be generated which, due to insufficient contrast, make text unreadable for readers with color vision deficiencies, or even for those with normal color vision. In the case of images, they can sink into a background or become too inconspicuous. This problem can happen in marketing materials when objects receive indiscriminable color combinations. This problem can be very subtle. For example, corporations may change their color palettes. Marketing materials that have been generated at an earlier point in time may no longer comply with the current palette and create confusion in the customer. In a variable data printing job, older material that was generated based on an older version of a color palette, may be printed with substitute colors from an updated color palette, and two previously very different colors could be mapped into close colors, causing discriminability issues.

Previously, the discriminability of objects in a print was verified visually on a proof print. In the case of variable data printing, this task is too onerous to be practical, because each printed piece is different. An automated solution to this problem is desirable. There are tools to automatically build pleasing color palettes for electronic documents, but these tools apply to the authoring phase, not to the production phase. In particular, these tools do not check the discriminability of objects.

Another issue involved with variable data printing relates to the color of frames that surround images in printed materials. Previously, in automated publishing or variable data systems, it was common to have a fixed frame color, or to select a random color. However, the use of fixed frame colors or random colors can result in color discriminability issues. Previously, when esthetics were important, a frame color was selected manually for each picture, which is a process that is not practical in a variable data printing solution. An automated solution to this problem is desirable.

### SUMMARY

One form of the present invention provides an automated method for proofing a page for color discriminability problems. The method includes converting a first color of a first object appearing on the page and a second color of a second object appearing on the page to a perceptually uniform color space. The method includes identifying a difference between the first color and the second color in the perceptually uniform color space. The method includes comparing the difference to a threshold to determine if the first color and the second color are discriminable.

### BRIEF DESCRIPTION OF THE DRAWINGS

FIG. 1 is a diagram illustrating an example page that could be created with an automated page layout system in a variable data printing process, and color problems that can occur in such a process.

FIG. 2 is block diagram illustrating a computer system suitable for implementing one embodiment of the present invention.

FIG. 3 is a flow diagram illustrating a method for automatically identifying color problems in a variable data printing process according to one embodiment of the present invention.

FIG. 4 is a diagram illustrating a technique for determining a new color combination in the method shown in FIG. 3 according to one embodiment of the present invention.

FIG. 5 is a diagram illustrating a page with images and image frames.

FIG. 6 is a flow diagram illustrating a method for automatically determining an appropriate color for an image frame according to one embodiment of the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” etc., may be used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following Detailed Description, therefore, is not to be taken in a limiting sense, and the scope of the present invention is defined by the appended claims.

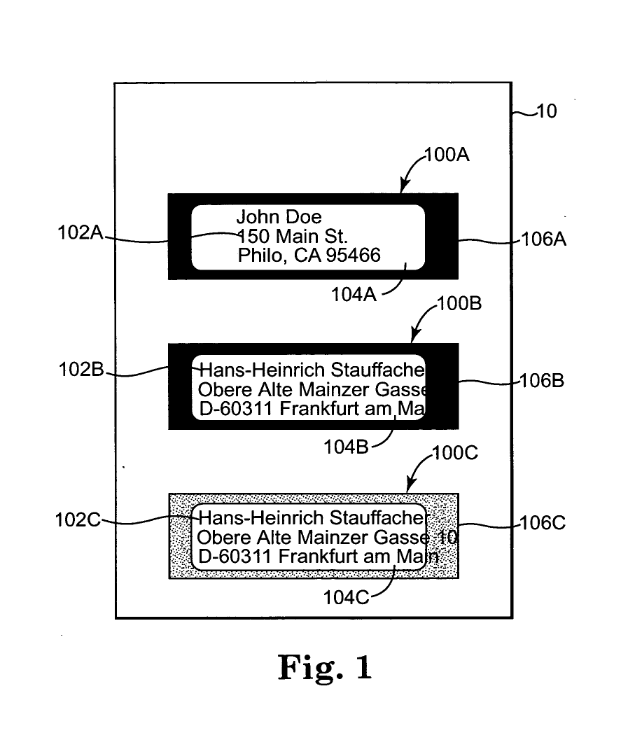

FIG. 1 is a diagram illustrating an example page 10 that could be created with an automated page layout system in a variable data printing process, and color problems that can occur in such a process. It will be understood by persons of ordinary skill in the art that, although objects may be shown in black and white or grayscale in the Figures, embodiments of the present invention are applicable to objects of any color. A concept that is used in one embodiment of the present invention is the concept of “color discriminability.” Color discriminability, according to one form of the invention, refers to the ability of an ordinary observer to quickly recognize a colored object or element on top of another colored object or element. Color discriminability is different than color difference, which is based solely on thresholds, and is different than distinct color, which refers to media robustness. The colors of two overlapping objects or elements are discriminable when the colors can quickly or instantly be told apart by an ordinary observer.

As shown in FIG. 1, page 10 includes three shipping labels 100A-100C (collectively referred to as shipping labels 100). Shipping label 100A includes foreground text object 102A, a first colored background object 104A, and a second colored background object 106A. First background object 104A is substantially rectangular in shape, and has a very light color (e.g., white). Second background object 106A surrounds first background object 104A, and is darker in color than first background object 104A. For shipping label 100A, the text in text object 102A fits entirely within the background object 104A. There is good contrast between the text object 102A and the background object 104A, and there are no color discriminability issues that need to be addressed for this particular shipping label 100A. However, in a variable data printing application, the text for the shipping labels 100 will vary, which can cause a problem like that shown in shipping label 100B.

Shipping label 100B includes foreground text object 102B, a first colored background object 104B, and a second colored background object 106B. First background object 104B is substantially rectangular in shape, and has a very light color (e.g., white). Second background object 106B surrounds first background object 104B, and is darker in color than first background object 104B. For shipping label 100B, the text in text object 102B does not fit entirely within the background object 104B, but rather a portion of the text overlaps the background object 106B. The text object 102B is the same or very similar in color to the background object 106B, and the portion of the text that overlaps the background object 106B is not visible. The foreground and the background colors are not discriminable for shipping label 100B.

Shipping label 100C includes foreground text object 102C, a first background object 104C, and a second colored background object 106C. For shipping label 100C, the text in text object 102C does not fit entirely within the background object 104C, but rather a portion of the text overlaps the background object 106C. The text object 102C is darker in color than the background object 106C, and the portion of the text that overlaps the background object 106C is visible. The foreground and the background colors are discriminable for shipping label 100C.

In a variable data printing job, it is not typically practical to proof every generated page. Automatic layout re-dimensioning works for some situations, but re-dimensioning algorithms, such as an algorithm based on the longest address for a mailing label, are driven by a few unusual cases, rather than the most likely data. For the mailing label example illustrated in FIG. 1, the problem can be solved by using a different font, such as a condensed or smaller font, making the label area larger, or splitting the address on multiple lines. However, in many situations, automatically selecting compatible colors for a page is a more convenient solution, and provides more visually pleasing results. Further, when the variable content is an image, for example, changing the background color may be the only solution. For an image over a colored background, if the image is close in color to the background, the image may blend into the background, causing the depicted object to essentially disappear.

In the examples illustrated in FIG. 1, the foreground objects are text objects. It other embodiments, the foreground objects are image objects, or other types of objects. An object, according to one form of the invention, refers to any item that can be individually selected and manipulated, such as text, shapes, and images or pictures that appear on a display screen. Examples of objects include text, images, tables, columns of information, boxes of data, graphs of data, audio snippets, active pages, animations, or the like. The images may be drawings or photographs, in color or black and white.

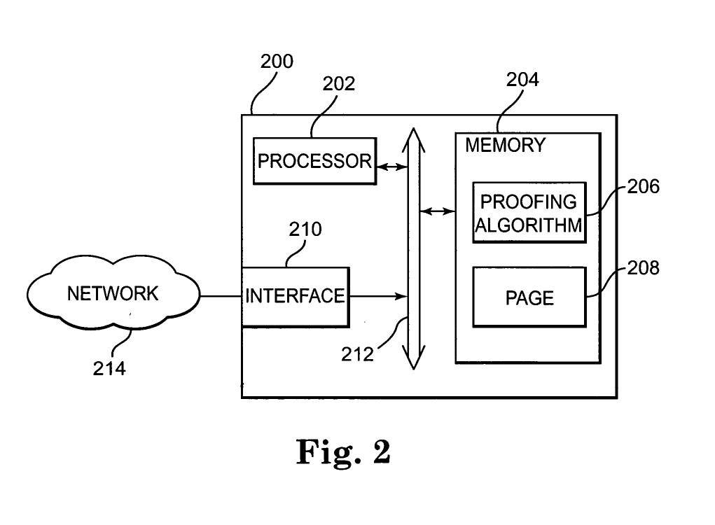

FIG. 2 is block diagram illustrating a computer system 200 suitable for implementing one embodiment of the present invention. As shown in FIG. 2, computer system 200 includes processor 202, memory 204, and network interface 210, which are communicatively coupled together via communication link 212. Computer system 200 is coupled to network 214 via network interface 210. Network 214 represents the Internet or other type of computer or telephone network. It will be understood by persons of ordinary skill in the art that computer system 200 may include additional or different components or devices, such as an input device, a display device, an output device, as well as other types of devices.

In one embodiment, memory 204 includes random access memory (RAM) and read-only memory (ROM), or similar types of memory. In one form of the invention, memory 204 includes a hard disk drive, floppy disk drive, CD-RQM drive, or other type of non-volatile data storage. In one embodiment, processor 202 executes information stored in the memory 204, or received from the network 214.

As shown in FIG. 2, proofing algorithm 206 and page 208 are stored in memory 204. In one embodiment, processor 202 executes proofing algorithm 206, which causes computer system 200 to perform various proofing functions, including proofing functions to identify color discriminability issues for page 208. In one embodiment, computer system 200 is configured to execute algorithm 206 to automatically proof objects on pages, such as page 208, for visual discriminability problems or errors, and compute suggestions to solve the errors, or automatically correct the errors. In one form of the invention, computer system 200 verifies a layout to be printed in a variable data print job for discriminability of all objects placed in the layout. In one embodiment, computer system 200 compares the color of two objects to assess their discriminability to an observer, such as the discriminability of text or images placed over a colored background. In one embodiment, computer system 200 generates an error log identifying discriminability issues for subsequent manual correction, and suggests discriminable color combinations that could be used to correct the discriminability problems. In another embodiment, computer system 200 corrects color discriminability problems “on-the-fly.”

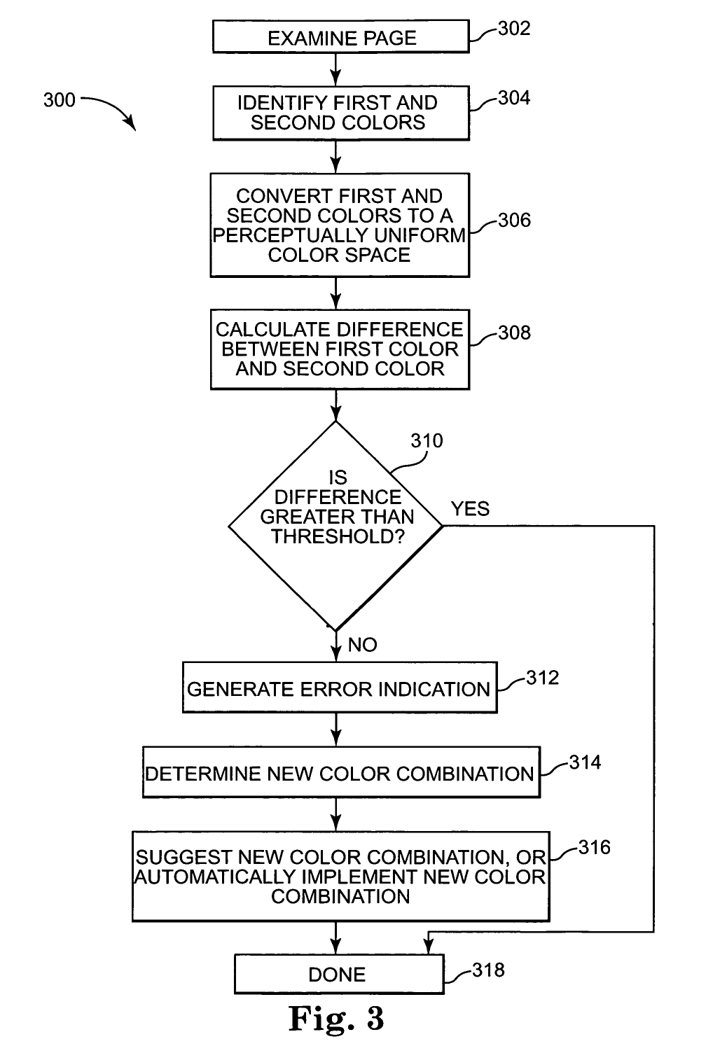

In one form of the invention, computer system 200 is configured to compute a discriminable color for a frame that surrounds an image, as well as blend frame colors for multiple frames on a spread. The computed frame colors are more visually pleasing than using fixed frame colors, or a random selection of frame colors. These and other functions performed by computer system 200 according to embodiments of the present invention are described in further detail below with reference to FIGS. 3-6.

In one form of the invention, the pages to be proofed by computer system 200, such as page 208, are automatically generated pages that are generated as part of a variable data printing process, and that are received by computer system 200 from network 214, or from some other source. Techniques for automatically generating pages of information are known to those of ordinary skill in the art, such as those disclosed in commonly assigned U.S. Patent Application Publication No. 2004/0122806 A1, filed Dec. 23, 2002, published Jun. 24, 2004, and entitled APPARATUS AND METHOD FOR MARKET-BASED DOCUMENT LAYOUT SELECTION, which is hereby incorporated by reference herein.

It will be understood by a person of ordinary skill in the art that functions performed by computer system 200 may be implemented in hardware, software, firmware, or any combination thereof. The implementation may be via a microprocessor, programmable logic device, or state machine. Components of the present invention may reside in software on one or more computer-readable mediums. The term computer-readable medium as used herein is defined to include any kind of memory, volatile or non-volatile, such as floppy disks, hard disks, CD-ROMs, flash memory, read-only memory (ROM), and random access memory. It is intended that embodiments of the present invention may be implemented in a variety of hardware and software environments.

FIG. 3 is a flow diagram illustrating a method 300 for automatically identifying color problems in a variable data printing process according to one embodiment of the present invention. In one embodiment, computer system 200 (FIG. 2) is configured to perform method 300 by executing proofing algorithm 206. In one form of the invention, method 300 determines discriminable color combinations for background and foreground objects appearing on a page, so that text remains visible and images do not vanish into the background in variable data printing applications.

At 302, computer system 200 examines a page 208, and identifies overlapping objects on the page 208. In one embodiment, computer system 200 identifies at least one foreground object on the page 208 and at least one background object on the page 208, wherein the foreground and background objects at least partially overlap. In one embodiment, the foreground object is text or an image. At 304, computer system 200 identifies a first color and a second color appearing on the page 208. In one embodiment, the first color is a color of a foreground object identified at 302, and the second color is a color of a background object identified at 302.

In one embodiment, the colors identified at 304 are device dependent colors. A device dependent color classification model provides color descriptor classifications or dimensions, that are derived from, and which control, associated physical devices. Such device dependent color classification models include the additive red, green, and blue (RGB) phosphor color model used to physically generate colors on a color monitor, and the subtractive cyan, yellow, magenta, and black (CYMK) color model used to put colored inks or toners on paper. These models are not generally correlated to a human color perceptual model. This means that these device dependent color models provide color spaces that treat color differences and changes in incremental steps along color characteristics that are useful to control the physical devices, but that are not validly related to how humans visually perceive or describe color. A large change in one or more of the physical descriptors of the color space, such as in the R, G, or B dimensions, will not necessarily result in a correspondingly large change in the perceived color.

Other color models exist which are geometric representations of color; based on the human perceptual attributes of hue, saturation, and value (or brightness or lightness) dimensions (HSV). While providing some improvement over the physically based RGB and CMYK color models, these color specifications are conveniently formulated geometric representations within the existing physically based color models, and are not psychophysically validated perceptually uniform color models.

Referring again to FIG. 3, after identifying the device dependent first and second colors at 304, at 306 in method 300, computer system 200 converts the device dependent first and second colors to a perceptually uniform color space. A uniform color space, which is based on an underlying uniform color model, attempts to represent colors for the user in a way that corresponds to human perceptual color attributes that have been actually measured. One such device independent color specification system has been developed by the international color standards group, the Commission Internationale de I'Eclairage (“CIE”). The CIE color specification employs device independent “tristimulus values” to specify colors and to establish device independent color models by assigning to each color a set of three numeric tristimulus values according to its color appearance under a standard source illumination as viewed by a standard observer. The CIE has recommended the use of two approximately uniform color spaces for specifying color: the CIE 1976 (L*u*v*) or the CIELUV color space, and the CIE 1976 (L*a*b*) color space (hereinafter referred to as “CIELAB space”).

In one embodiment, at 306 in method 300, computer system 200 converts the device dependent first and second colors to the CIELAB space. However, it is intended that embodiments of the present invention may use any of the currently defined perceptually uniform color spaces, such as the CIELUV space, the Munsell color space, and the OSA Uniform Color Scales, or in a future, newly defined perceptually uniform color space.

At 308 in method 300, computer system 200 calculates a difference between the first and the second color in the CIELAB space. In the CIELAB space, the numerical magnitude of a color difference bears a direct relationship to a perceived color appearance difference. Colors specified in CIELAB space with their L*, a*, and b* coordinates are difficult to visualize and reference as colors that are familiar to users. In this disclosure, for purposes of referring to colors by known names and according to human perceptual correlates, colors specified in CIELAB space are also referenced by the human perceptual correlates of lightness (L), chroma (C), and hue (H). A color is then designated in the CIELAB space with a coordinate triplet (L, C, H), representing the lightness, chroma, and hue, respectively, of the color. The CIELAB correlates for lightness, chroma, and hue are obtained by converting the coordinates from Cartesian coordinates to cylindrical coordinates.

In the CIELAB space, the Euclidean distance of two colors is proportional to their perceived distance. In this space, colors can be tweaked until they are discriminable. A metric unit used in one embodiment of the present invention is a just-noticeable difference (JND). One unit in the CIELAB space corresponds roughly to one just-noticeable difference. If one looks at two close colors in Cartesian coordinates in the CIELAB space, regardless of where these two colors are located in the CIELAB space, if the Euclidean distance between the two colors is the same in one pair of locations as a different pair of locations, the two colors will be perceived as having the same amount of difference in terms of just noticeable differences. If two colors are separated by a threshold number of just-noticeable differences, the two colors are deemed to be discriminable.

In one embodiment, at 308 in method 300, computer system 200 computes a difference value representing the number of just noticeable differences between the first color and the second color. In one embodiment, the difference value represents the Euclidean distance between the first color and the second color in the CIELAB space. In the case of figurative objects, color discriminability can be determined based on color contrast. However, in one form of the invention, color discriminability is determined based on lightness contrast, because, in general, lightness contrast is best for text readability and is robust for readers with deficient color vision. To a first approximation, the human visual system is more sensitive to changes in lightness than to changes in chroma. Thus, in another form of the invention, at 308 in method 300, computer system 200 computes a difference value that represents the difference between the lightness value for the first color and the lightness value for the second color in the CIELAB space.

At 310, computer system 200 determines whether the difference value calculated at 308 is greater than a threshold value. If it is determined at 310 that the difference value calculated at 308 is greater than the threshold, the first and the second colors are deemed to be discriminable, and the method 300 jumps to 318, which indicates that the method 300 is done. If it is determined at 310 that the difference value calculated at 308 is not greater than the threshold, the first and the second colors are deemed to not be discriminable, and the method 300 moves to 312. Based on an empirical set-up using an sRGB LCD display monitor and a dry toner color laser printer, it has been determined that a value of 27 CIELAB units on the lightness axis is the lowest bound for discriminability of a pair of background and foreground colors. Thus, in one embodiment, the threshold used at 310 in method 300 is 27 CIELAB lightness units.

At 312, computer system 200 generates an error indication, which indicates that the first and the second colors are not discriminable. In one embodiment, computer system 200 maintains an error log that identifies all color discriminability issues for a given variable data printing job.

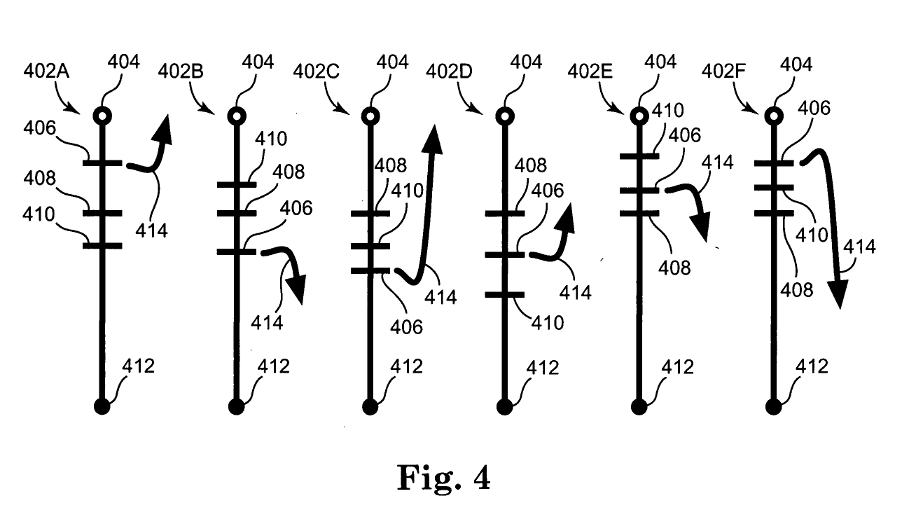

At 314, computer system 200 determines a new, discriminable color combination for the first and the second colors. In one embodiment, computer system 200 determines a new color for the first color, such that the new first color and the second color are discriminable. In another embodiment, computer system 200 determines a new color for the second color, such that the new second color and the first color are discriminable. In yet another embodiment, computer system 200 determines a new color for the first color and the second color, such that the two new colors are discriminable. A technique for determining a new color combination at 314 in method 300 according to one embodiment of the invention, is described in further detail below with respect to FIG. 4. In one form of the invention, at 314, computer system 200 selects or determines colors to use from a limited palette of colors, such as a corporate color palette.

After determining a new color combination at 314, method 300 moves to 316. In one embodiment, at 316, computer system 200 provides a suggestion to the user to use the new color combination identified at 314. In this embodiment, the user may choose to use the new color combination, or keep the original colors. In another embodiment, at 316, computer system 200 converts the color combination identified at 314 to a corresponding device dependent color combination, and automatically replaces the original color combination with the new color combination. Method 300 then moves to 318, which indicates that the method 300 is done.

In one embodiment, method 300 provides robust color selections, such that objects are discriminable to people with color vision deficiencies, as well as those people that have normal color vision. In one embodiment, method 300 relies on lightness contrast between two colors, which helps to make the method 300 robust for those with color vision deficiencies. In another embodiment, a color vision deficiency model is used by computer system 200, and computer system 200 is configured to determine if two colors are discriminable based on the color vision deficiency model. The color vision deficiency model helps to ensure that colors are not only discriminable to people with normal vision, but also to people with a color vision deficiency.

FIG. 4 is a diagram illustrating a technique for determining a new color combination at 314 in method 300 (FIG. 3) according to one embodiment of the present invention. FIG. 4 shows six lightness scales 402A-402F (collectively referred to as scales 402), which each represent a lightness axis in the CIELAB space. The top 404 of each of the scales 402 represents white, and the bottom 412 of each of the scales 402 represents black. The first color from method 300, which is a foreground color in one embodiment, is identified on each of the scales 402 by reference number 406. The second color from method 300, which is a background color in one embodiment, is identified on each of the scales 402 by reference number 410.

Also shown on each of the scales 402 is a lightness bias 408. The lightness range for each of the scales 402 can grossly be divided into a dark half (bottom half of the scales 402) with values between 0 and 50 units on the CIELAB lightness axis, and a light half (top half of the scales 402) with values between 50 and 100 units on the CIELAB lightness axis. In practice, even when a display monitor is accurately calibrated, it may still be deployed in incorrect viewing conditions. The glare effectively reduces a considerable portion of the shadow range. A similar effect also happens in printers, where low-cost papers are often substituted for the standard paper used in the calibration, resulting in soft half-tones and detail loss in shadow and very vivid areas. Based on an empirical set-up using an sRGB LCD display monitor and a dry toner color laser printer, it has been estimated that the effective mid-point between light and dark (i.e., the lightness bias 408) on scales 402 is 70 lightness units.

In one embodiment, a new color for the first color 406 is determined at 314 in method 300 based on the relative darkness and lightness of the first color 406 and the second color 410, and the position of the first and second colors 406 and 410 with respect to the lightness bias 408. In one embodiment, the lightness of the first color 406 is adjusted to obtain a new first color, and correspondingly, a new color combination. In one form of the invention, the lightness of the first color 406 is adjusted such that there are at least a threshold number of lightness units (e.g., 27 lightness units) separating the first color 406 and the second color 410 on the scale 402, and such that the first color 406 and the second color 410 are on opposite sides of the bias 408. An arrow 414 is shown by each of the scales 402, which indicates the direction that the lightness of the first color 406 is adjusted to obtain the new first color.

For the example color combination illustrated with respect to scale 402A, the lightness of the first color 406 is greater than the bias 408, and is greater than the lightness of the second color 410, and the lightness of the second color 410 is less than the bias 408. In this situation, as indicated by the arrow 414 for scale 402A, the lightness of the first color 406 is adjusted upward to obtain the new color.

For the example color combination illustrated with respect to scale 402B, the lightness of the first color 406 is less than the bias 408, and is less than the lightness of the second color 410, and the lightness of the second color 410 is greater than the bias 408. In this situation, as indicated by the arrow 414 for scale 402B, the lightness of the first color 406 is adjusted downward to obtain the new color.

For the example color combination illustrated with respect to scale 402C, the lightness of the first color 406 is less than the bias 408, and is less than the lightness of the second color 410, and the lightness of the second color 410 is less than the bias 408. In this situation, as indicated by the arrow 414 for scale 402C, the lightness of the first color 406 is adjusted upward above the bias 408 to obtain the new color.

For the example color combination illustrated with respect to scale 402D, the lightness of the first color 406 is less than the bias 408, and is greater than the lightness of the second color 410, and the lightness of the second color 410 is less than the bias 408. In this situation, as indicated by the arrow 414 for scale 402D, the lightness of the first color 406 is adjusted upward above the bias 408 to obtain the new color.

For the example color combination illustrated with respect to scale 402E, the lightness of the first color 406 is greater than the bias 408, and is less than the lightness of the second color 410, and the lightness of the second color 410 is greater than the bias 408. In this situation, as indicated by the arrow 414 for scale 402E, the lightness of the first color 406 is adjusted downward below the bias 408 to obtain the new color.

For the example color combination illustrated with respect to scale 402F, the lightness of the first color 406 is greater than the bias 408, and is greater than the lightness of the second color 410, and the lightness of the second color 410 is greater than the bias 408. In this situation, as indicated by the arrow 414 for scale 402F, the lightness of the first color 406 is adjusted downward below the bias 408 to obtain the new color.

In one form of the invention, at 314 in method 300, the lightness and the hue of the first color are adjusted. In another form of the invention, at 314 in method 300, the lightness and the chroma of the first color are adjusted. In yet another form of the invention, at 314 in method 300, the lightness, hue, and chroma of the first color are adjusted. In one embodiment, if the difference in the hues of the first and the second colors is less than a threshold value, the hue of the first color is adjusted at 314 in method 300 to increase the difference between the hues of the two colors above the threshold value. In another form of the invention, if the difference in the chroma of the first and the second colors is less than a threshold value, the chroma of the first color is adjusted to increase the difference between the chroma of the two colors above the threshold value.

In one embodiment, when a foreground object being analyzed by computer system 200 is an image that is placed over a colored background object, computer system 200 is configured to use method 300 to adjust the color of the background object, if necessary, to correct any discriminability problems. In this situation, according to one embodiment, computer system 200 computes a representative color for the image by averaging all, or a portion, of the colors of the image in a perceptually uniform color space (e.g., CIELAB space). Computer system 200 then compares the computed representative color and the background color, and adjusts the background color in the same manner as described above with respect to FIG. 4. In one form of the invention, computer system 200 computes a periphery color for the image by averaging the colors at a periphery portion of the image in a perceptually uniform color space. Computer system 200 then compares the computed periphery color and the background color, and adjusts the background color in the same manner as described above with respect to FIG. 4.

In another embodiment, when a foreground object being analyzed by computer system 200 is an image that is placed over a colored background object, rather than changing the background color, or in addition to changing the background color, computer system 200 is configured to determine whether an image frame should be used for the image object. In one form of the invention, computer system 200 is configured to automatically generate an image frame if there are color discriminability issues between the image and the background.

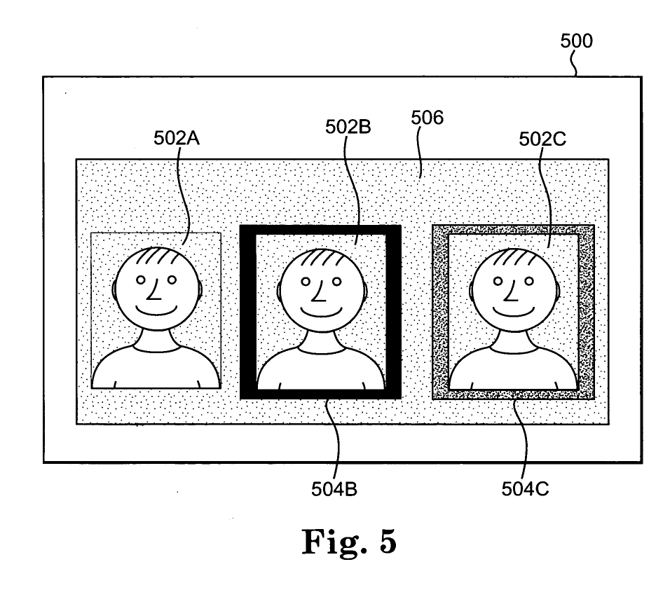

In one form of the invention, computer system 200 is also configured to automatically determine an appropriate color for an image frame. FIG. 5 is a diagram illustrating a page 500 with images 502A-502C and image frames 504B and 504C. As shown in FIG. 5, image 502A does not have an image frame. Image frame 504B surrounds the periphery of image 502B, and image frame 504C surrounds the periphery of image 502C. Images 502A-502C and image frames 504B and 504C are all positioned on a background 506, which has a relatively light color that is represented by low density stipple in FIG. 5. Since much of the image 502A is also relatively light, the image 502A does not really stand out, but rather the image 502A tends to blend into the background 506. In one embodiment, computer system 200 (FIG. 2) is configured to automatically identify this color discriminability issue for image 502A, and automatically adjust the color of the background 506 as described above with respect to FIG. 3. In another embodiment, computer system 200 is configured to automatically generate an image frame for the image 502A.

Image frame 504B represents a fixed frame with a color that is randomly selected by a computer, for example. There is a large contrast between the image frame 504B and the image 502B, as well as between the image frame 504B and the background 506. The large contrast tends to cause the image frame 504B to stand out and distract the viewer.

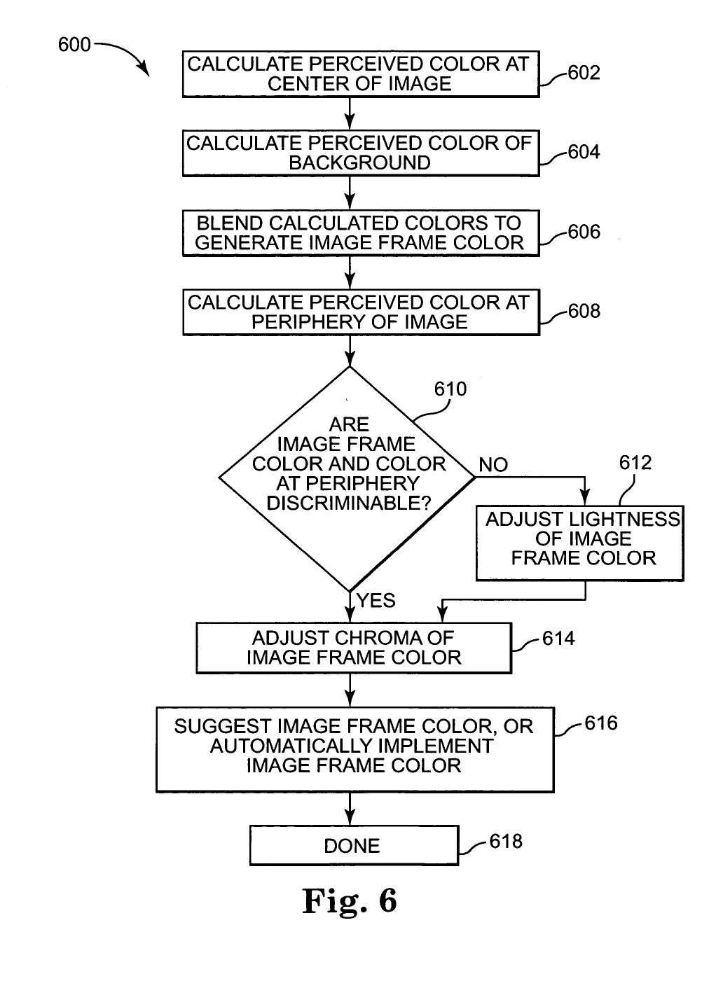

Image frame 504C represents a frame with a color (represented by stipple with a higher density than that used for background 506) that is automatically computed according to one form of the invention to help the image 502C to stand out, without causing distraction. A method for automatically determining an appropriate color for an image frame according to one form of the invention is described in further detail below with reference to FIG. 6.

The frames 504B and 504C shown in FIG. 5 are rectangular in shape with rectangular openings. However, it will be understood by persons of ordinary skill in the art that embodiments of the present invention are applicable to all types of frame shapes and sizes. The frames, or openings of the frames, can have any shape such as a square, rectangle, triangle, circle, oval, or star. This list is not exhaustive and more complex shapes, including non-geometric shapes, may be used.

FIG. 6 is a flow diagram illustrating a method 600 for automatically determining an appropriate color for an image frame according to one embodiment of the present invention. In one embodiment, computer system 200 (FIG. 2) is configured to perform method 600 by executing proofing algorithm 206. Method 600 is described below in the context of the image 502C and the image frame 504C shown in FIG. 5.

At 602, computer system 200 examines a center portion of image 502C and calculates a center portion color, which represents the perceived color at the center portion of the image 502C. In one embodiment, the center portion color is calculated at 602 by averaging the colors at the center portion of the image 502C in a perceptually uniform color space (e.g., CIELAB space). Averaging the colors in a perceptually uniform color space in this manner results in a color that would be perceived by a standard observer that squints at the image (or looks at the image from afar). In one embodiment, image 502C has a length, L, and a width, W. In one embodiment, the “center portion” of the image 502C examined at 602 is defined to be a rectangle having a length of 0.5 L, and a width of 0.5 W, which is centered about a center point of the image 502C. In other embodiments, other sizes or shapes may be used for the center portion of the image.

At 604, computer system 200 examines the background 506 on which the image 502C is placed, and calculates a background color, which represents the perceived color of the background 506. In one embodiment, if the background 506 includes more than one color, the background color is calculated at 604 by averaging the colors of the background 506 in the perceptually uniform color space.

At 606, computer system 200 blends the center portion color calculated at 602 with the background color calculated at 604 to determine an image frame color. The blend function performed at 606 according to one embodiment is a linear interpolation between the three coordinates of the center portion color and the background color in the perceptually uniform color space, which results in a range of colors between the center portion color and the background color. In one embodiment, the image frame color for frame 504C is selected by the computer system 200 to be the same as the color appearing in the center of the range of colors generated by the blend function at 606. In one embodiment, at 606, computer system 200 selects or determines an image frame color from a; limited palette of colors, such as a corporate color palette. In one embodiment, computer system 200 selects a color from the limited palette that is closest to the color appearing in the center of the range of colors generated by the blend function at 606.

At 608, computer system 200 examines a periphery portion of image 502C and calculates a periphery portion color, which represents the perceived color at the periphery portion of image 502C. In one embodiment, the periphery portion color is calculated at 608 by averaging the colors at the periphery portion of the image 502C in the perceptually uniform color space. In one embodiment, the periphery portion of image 502C represents all portions of the image 502C outside of the center portion of the image.

At 610, computer system 200 determines whether the image frame color determined at 606 is discriminable from the periphery portion color determined at 608. In one form of the invention, computer system 200 makes the discriminability determination at 610 in the perceptually uniform color space in the same manner as described above with respect to method 300 (FIG. 3). If it is determined at 610 that the two colors are not discriminable, the method 600 moves to 612. If it is determined at 610 that the two colors are discriminable, the method 600 moves to 614.

At 612, computer system 200 modifies the lightness of the image frame color determined at 606 in the perceptually uniform color space, such that the modified image frame color is discriminable from the periphery portion color calculated at 608. In one embodiment, the lightness of the image frame color is adjusted in the same manner as described above with respect to FIGS. 3 and 4.

At 614, the chroma of the image frame color determined at 612 is adjusted, if appropriate. In one embodiment, the chroma of the image frame color is adjusted so that the image 502C is at the same perceived plane or the same perceived depth as the background 506. The more vivid (i.e., higher chroma) the image frame color is, the more the image 502C that is framed appears to be before the background 506, and the less vivid (i.e., lower chroma) the image frame color is, the more the image 502C that is framed appears to sink back behind the background. After the chroma of the image frame color is adjusted at 614, the resulting image frame color is ready to be applied to the image frame 504C. In one embodiment, at 616, computer system 200 provides a suggestion to the user, which identifies the image frame color that should be used, as determined from method 600. In another embodiment, at 616, computer system 200 automatically generates a frame with a color determined from method 600 and converted to a device dependent color, or automatically changes the color of an existing image frame to a color determined from method 600 and converted to a device dependent color. Method 600 then moves to 618, which indicates that the method 600 is done.

In one embodiment, when multiple framed images appear on a page or a spread, computer system 200 is configured to automatically select a color for each image frame based on method 600. In another embodiment, when multiple framed images appear on a page or a spread, computer system 200 is configured to automatically select a color for each image frame based on method 600, and then blend the selected image frame colors to obtain a single image frame color that is used for all frames, so that the spread appears more uniform.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An automated method for proofing a page for color discriminability problems, the method comprising:
converting a first color of a first object appearing on the page and a second color of a second object appearing on the page to a perceptually uniform color space;
identifying a difference between the first color and the second color in the perceptually uniform color space; and
comparing the difference to a threshold to determine if the first color and the second color are discriminable.

2. The automated method of claim 1, wherein the first color and the second color are converted from a device dependent color space to the perceptually uniform color space.

3. The automated method of claim 1, wherein the first object is text and the second object is a colored background object.

4. The automated method of claim 1, wherein the first object is an image and the second object is a colored background object.

5. The automated method of claim 1, wherein the first and the second objects at least partially overlap on the page.

6. The automated method of claim 1, wherein the difference represents a number of just noticeable differences between the first color and the second color in the perceptually uniform color space.

7. The automated method of claim 6, wherein the first color and the second color are deemed to be discriminable if the difference between the first color and the second color is greater than a threshold number of just noticeable differences.

8. The automated method of claim 1, wherein the difference represents a difference in a number of lightness units between the first color and the second color in the perceptually uniform color space.

9. The automated method of claim 8, wherein the first color and the second color are deemed to be discriminable if the difference is greater than a threshold number of lightness units.

10. The automated method of claim 1, wherein the first object is an image, and wherein the step of converting a first color of a first object comprises averaging colors of the image in the perceptually uniform color space to obtain a representative color for the image that is used in the step of identifying a difference.

11. The automated method of claim 1, wherein the first object is an image, and wherein the step of converting a first color of a first object comprises averaging colors of a periphery portion of the image in the perceptually uniform color space to obtain a representative color for the image that is used in the step of identifying a difference.

12. The automated method of claim 1, and further comprising:
generating an error indication if it is determined that the first color and the second color are not discriminable.

13. The automated method of claim 1, and further comprising:
determining a new discriminable color combination for the first and the second colors if it is determined that the first color and the second color are not discriminable.

14. The automated method of claim 13, wherein the step of determining a new discriminable color combination comprises:
adjusting a lightness value of at least one of the first color and the second color.

15. The automated method of claim 14, wherein the lightness value is adjusted based on the threshold.

16. The automated method of claim 15, wherein the lightness value is adjusted based on the threshold, and based on lightness values of the first and the second colors with respect to a bias lightness value.

17. The automated method of claim 16, wherein the bias lightness value represents an effective mid-point between light and dark regions on a lightness axis in the perceptually uniform color space.

18. The automated method of claim 14, wherein the step of determining a new discriminable color combination further comprises:
adjusting at least one of a chroma value and a hue value of at least one of the first color and the second color.

19. The automated method of claim 13, wherein the new discriminable color combination is determined from a limited palette of colors.

20. The automated method of claim 13, and further comprising:
providing a suggestion to a user to use the new color combination for the first and the second objects.

21. The automated method of claim 13, and further comprising:
automatically changing the first and the second colors to the new color combination.

22. The automated method of claim 1, wherein the page is generated by an automated page layout system.

23. The automated method of claim 1, wherein the page is generated in a variable data printing process.

24. A system for automatically identifying color discriminability problems of objects appearing on a page, the system comprising:
a memory for storing the page; and
a processor coupled to the memory for converting a first color associated with a first object on the page and a second color associated with a second object on the page to a perceptually uniform color space, and identifying whether the first color and the second colors are discriminable based on a difference between the first and the second color in the perceptually uniform color space.

25. The system of claim 24, wherein the first color and the second color are converted from a device dependent color space to the perceptually uniform color space.

26. The system of claim 25, wherein the difference represents a number of just noticeable differences between the first color and the second color in the perceptually uniform color space.

27. The system of claim 26, wherein the first color and the second color are deemed to be discriminable if the difference between the first and the second colors is greater than a threshold number of just noticeable differences.

28. The system of claim 24, wherein the difference represents a difference in a number of lightness units between the first color and the second color in the perceptually uniform color space.

29. The system of claim 28, wherein the first color and the second color are deemed to be discriminable if the difference between the first and the second colors is greater than a threshold number of lightness units.

30. The system of claim 24, wherein the first object is an image, and wherein converting a first color associated with a first object on the page comprises averaging colors of the image in the perceptually uniform color space to obtain a representative color for the image.

31. The system of claim 24, wherein the processor is configured to determine a new discriminable color combination for the first and the second colors if it is determined that the first color and the second color are not discriminable.

32. The system of claim 31, wherein the new discriminable color combination is determined by adjusting a lightness value of at least one of the first color and the second color in the perceptually uniform color space.

33. The system of claim 32, wherein the new discriminable color combination is determined by adjusting at least one of a chroma value and a hue value of at least one of the first color and the second color in the perceptually uniform color space.

34. A system for proofing a page for color discriminability problems, the page including a first object and a second object, the system comprising:
means for converting a first color associated with the first object and a second color associated with the second object to a perceptually uniform color space;
means for identifying a difference between the first color and the second color in the perceptually uniform color space; and
means for determining whether the difference is greater than a threshold, thereby indicating that the first color and the second color are discriminable.

35. A computer-readable medium having computer-executable instructions for performing a method of identifying color discriminability problems of objects appearing on a page to be printed, comprising:
identifying a first color associated with a first object appearing on the page;
identifying a second color associated with a second object appearing on the page;
converting the first and the second colors to a perceptually uniform color space; and
determining whether the first color and the second color are discriminable based on a difference between the first and the second colors in the perceptually uniform color space.

36. The computer-readable medium of claim 35, wherein the method further comprises:
determining a new discriminable color combination for the first and the second colors if it is determined that the first color and the second color are not discriminable.
